(19) United States
(12) Patent Application Publication
(10) Pub. No.: US 2005/0271817 A1
(43) Pub. Date: Dec. 8, 2005

(54) Method for preparation of aluminum oxide thin film

(76) Inventors: Yunsoo Kim, Daejeon (KR); Ki-Seok An, Daejeon (KR); Sun-Sook Lee, Daejeon (KR); Taek-Mo Chung, Daejeon (KR); Wontae Cho, Busan (KR); Kiwhan Sung, Incheon (KR)

Correspondence Address: ANDERSON, KILL & OLICK, P.C., 1251 AVENUE OF THE AMERICAS, NEW YORK,, NY, 10020-1182, US

(21) Appl. No.: 10/523,374

(22) PCT Filed: Jul. 29, 2003
(86) PCT No.: PCT/KR03/01511

§ 371 Date: Feb. 2, 2005

(30) Foreign Application Priority Data
Aug. 2, 2002 (KR) 10-2002-0045746

(51) Int. Cl. C23C 16/00

(52) U.S. Cl. 427/255.28

(57) ABSTRACT

An aluminum oxide film is formed on a substrate by a process comprising A) bringing the vapor of a dialkylaluminum alkoxide into contact with the substrate mounted in a deposition reactor so that an aluminum-containing adsorption layer is formed on the substrate; B) removing the unreacted aluminum compound and by-products from the reactor; C) introducing an oxygen source into the reactor so that the oxygen source reacts with the aluminum-containing adsorption layer to form an aluminum oxide layer, and D) removing the unreacted oxygen source and by-products from the reactor.

### FIELD OF THE INVENTION

The present invention relates to a method for the preparation of an aluminum oxide thin film by atomic layer deposition (ALD) under mild conditions.

### BACKGROUND OF THE INVENTION

Aluminum oxide is a dielectric material having a wide band gap of about 9 eV and a large band offset with respect to silicon. The dielectric constant of aluminum oxide is more than two times as high as that of silicon oxide. Therefore, aluminum oxide may be used to form a dielectric layer on a silicon substrate. Further, when a film of a high dielectric material such as zirconium dioxide is formed on a silicon substrate, an aluminum oxide film may be used as a diffusion barrier (see Jeon et al., “Utrathin nitrided-nanolaminate (Al₂O₃/ZrO₂/Al₂O₃) for metal-oxide-semiconductor gate dielectric application,” J. Vac. Sci. Technol. B 2002, 20, 1143-1145; and H. S. Chang et al., “Excellent thermal stability of Al₂O₃/ZrO₂/Al₂O₃ stack structure for metal-oxide-semiconductor gate dielectric application,” Appl. Phys. Lett. 2002, 80, 3385-3387).

An aluminum oxide thin layer may be deposited on a substrate by atomic layer deposition (ALD) or metal organic chemical vapor deposition (MOCVD). ALD is conducted by alternately supplying alummum and oxygen precursors to be deposited on a substrate. Exemplary aluminum precursors are aluminum trichloride, trimethylaluminum, triethylaluminum, chlorodimethylalumium, aluminum ethoxide, aluminum isopropoxide (see M. Leskelä et al., “ALD precursor chemistry: Evolution and future challenges,” J. Phys. IV 1999, 9, Pr8-837-Pr8-852). For example, trimethylaluminum (Me₃Al) may be used as the aluminum precursor together with water or oxygen at a deposition temperature of 200-450° C., but a silicon oxide or aluminum silicate film having a thickness of a few nanometers is usually formed between the silicon substrate and the aluminum oxide film formed (see Räisänen et al., “Atomic layer deposition of Al₂O₃ films using AlCl₃ and Al(OⁱPr)₃ as precursors,” J. Mater. Chem. 2002, 12, 1415-1418; and Klein et al., “Evidence of aluminum silicate formation during vapor deposition of amorphous Al₂O₃ thin films on Si(100),” Appl. Phys. Lett. 1999, 75, 4001-4003). Such a silicon oxide or aluminum silicate film formed at the interface between the silicon substrate and aluminum oxide layer deteriorates the electrical properties of semiconductor devices. In order to solve such problems, there has been reported a method for deposition of an aluminum oxide film using aluminum trichloride (AlCl₃) or trimethylaluminum (Me₃Al) as an aluminum precursor and aluminum isopropoxide [Al(OⁱPr)₃] as an oxygen precursor instead of water or oxygen (see Ritala et al., “Atomic Layer Deposition of Oxide Thin Films with Metal Alkoxides as Oxygen Sources,” Science 2000, 288, 319-321; and Räisänen et al., “Atomic layer deposition of Al₂O₃ films using AlCl₃ and Al(OⁱPr)₃ as precursors,” J. Mater. Chem. 2002, 12, 1415-1418).

There is also reported a method for fabricating an aluminum oxide thin film using trimethylaluminum (Me₃Al) and isopropyl alcohol (see Jeon et al., “Atomic layer deposition of Al₂O₃ thin film using trimethylaluminum and isopropyl alcohol,” J. Electrochem. Soc. 2002, 149, C306-C310). However, trimethyl aluminum (Me₃Al) is highly flammable and aluminum trichloride (AlCl₃) produces corrosive hydrogen chloride.

On the other hand, metal organic chemical vapor deposition (MOCVD) processes for depositing thin aluminum oxide films using such non-flammable, non-corrosive precursors as dimethylaluminum isopropoxide [(CH₃)₂AlOCH(CH₃)₂; Me₂AlOⁱPr], dimethylaluminum tert-butoxide [(CH₃)₂AlOC(CH₃)₃; Me₂AlO^{t}Bu], diethylaluminum isopropoxide [(CH₃CH₂)₂AlOCH(CH₃)₂; Et₂AlOⁱPr], etc. have been reported (see Koh et al., “Chemical vapor deposition of Al₂O₃ films using highly volatile single sources,” Thin Solid Films 1997, 304, 222-224; Barreca et al., “Growth Kinetics of Al₂O₃ Thin Films Using Aluminum Dimethylisopropoxide,” The 197^{th} Meeting of the Electrochemical Society, Meeting Abstracts, Vol. 2000-1, Abstract No. 908; Barreca et al., “Al₂O₃ thin films from aluminum dimethylisopropoxide by metal-organic chemical vapour deposition,” J. Mater. Chem. 2000, 10, 2127-2130). However, MOCVD requires a relatively high deposition temperature and it is difficult to precisely control the film thickness, besides the problem that the surface of an aluminum oxide film formed is rather rough.

### SUMMARY OF THE INVENTION

It is, therefore, an object of the present invention to provide a process for fabricating an aluminum oxide film having good uniformity and conformality at a lower temperature using an atomic layer deposition process.

In accordance with the present invention, there is provided a process for preparing an aluminum oxide film on a substrate which comprises:

A) bringing the vapor of a dialkylaluminum alkoxide into contact with the substrate mounted in a deposition reactor so that an aluminum-containing adsorption layer is formed on the substrate;

B) removing the unreacted aluminum compound and by-products from the reactor;

C) introducing an oxygen source into the reactor so that the oxygen source reacts with the aluminum-containing adsorption layer to form an aluminum oxide layer; and

D) removing the unreacted oxygen source and by-products from the reactor.

### BRIEF DESCRIPTION OF THE DRAWINGS

The above and other objects and features of the present invention will become apparent from the following description of the invention, when taken in conjunction with the accompanying drawings which respectively show:

FIG. 1: a schematic diagram of the materials feed steps in accordance with a preferred embodiment of the present invention; and

FIG. 2: an X-ray photoelectron spectrum of the aluminum oxide film obtained in Example 1.

### DETAILED DESCRIPTION OF THE INVENTION

The present invention provides an atomic layer deposition method for preparing an aluminum oxide film on a substrate by alternately introducing an aluminum precursor and an oxygen precursor into a deposition reactor in which the substrate is maintained at a uniform temperature. The reactor is purged after each deposition step to remove remaining reactants and by-products by applying a vacuum or supplying such an inert gas as argon.

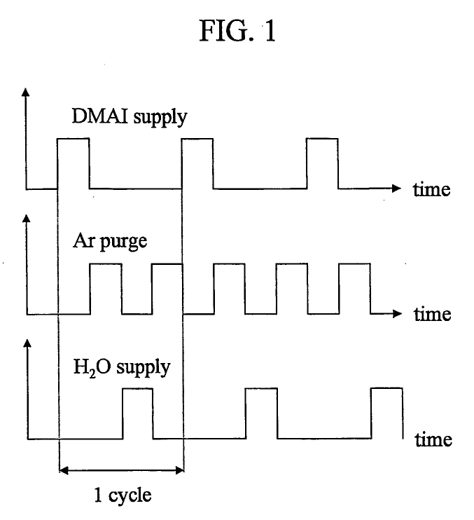

FIG. 1 depicts a schematic diagram of the materials flow steps in accordance with the present invention. The process comprises a cycle of four steps, an aluminum precursor adsorption (step A), the first purge (step B), an oxygen precursor adsorption (step C) and the second purge (step D). Each cycle consisting of the steps A to D may be repeated until an aluminum oxide film of a desired thickness is obtained.

The inventive process may be conducted by positioning a substrate in a deposition reactor equipped with a vacuum pump and introducing a dialkylaluminum alkoxide as an aluminum precursor so that an aluminum-containing adsorption layer is formed on the surface of the substrate.

A dialkylaluminum alkoxide of the following formula is preferred:
R¹₂—Al—O—R²

wherein R¹ and R² are each independently a C₁-C₄ alkyl.

More preferably, the aluminum source is selected from the group consisting of dimethylaluminum isopropoxide, dimethylaluminum tert-butoxide, diethylaluminum isopropoxide, dimethylaluminum sec-butoxide and a mixture thereof.

In accordance with a preferable embodiment of the present invention, the step of forming an aluminum-containing adsorption layer on the substrate, or the step of introducing oxygen source is conducted for a period of 0.1 s or longer per cycle, which may be controlled by adjusting the flow rates of the aluminum precursor and oxygen source introduced into the reactor.

After step A, the unreacted aluminum precursor and by-products are removed from the reactor by evacuation or by purging with argon (the first purging step).

When the first purging step is completed, an oxygen source, preferably water, is introduced into the reactor so as to allow the oxygen source to react with the aluminum-containing adsorption layer on the substrate. In accordance with a preferred embodiment of the present invention, the reaction time is 0.1 s or longer per cycle (step C).

After the step of supplying an oxygen source, the unreacted oxygen source and by-products are removed from the reactor by purging with argon or evacuating with a vacuum pump (the second purging step).

In accordance with the present invention, an aluminum oxide film is formed by ALD while maintaining the substrate at a low temperature in the range of 100-300° C., preferably 100-200° C. Such a low temperature deposition process is preferable since the diffusion between the substrate and aluminum oxide film is minimized.

In accordance with a preferred example of the present invention, an aluminum oxide film having excellent characteristics may be formed under mild conditions by using dimethylaluminum isopropoxide or dimethylaluminum sec-butoxide as an aluminum precursor and water as an oxygen source. Alternatively, as the oxygen source, oxygen or ozone may be used.

The present invention is further described and illustrated in the following Examples, which are, however, not intended to limit the scope of the present invention.

### EXAMPLE 1

A silicon substrate was cleaned with hydrofluoric acid and positioned in an atomic layer deposition reactor (Genitech Inc.). The reactor was evacuated with a vacuum pump and set at 150° C. The aluminum precursor container was charged with dimethylaluminum isopropoxide (DMAI) and heated to a temperature in the range 70-90° C. so that the vapor pressure of the aluminum compound could be controlled at a preset value. Water was used as an oxygen source. When the temperatures of the reactor, the aluminum precursor inlet tube and the aluminum precursor container were stabilized at preset values, a series of reaction steps as shown in FIG. 1 were conducted. Each step was conducted for 0.5 s, and each cycle was repeated thirty (30) times to obtain an aluminum oxide film having a thickness of 3.2 nm.

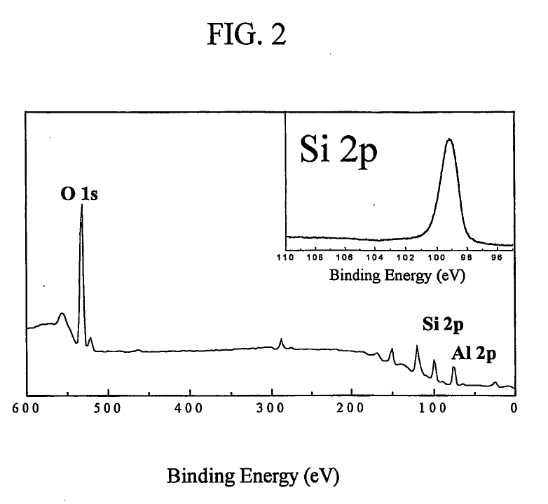

FIG. 2 is an X-ray photoelectron spectrum of the aluminum oxide film obtained in Example 1. Photoelectron peaks corresponding to aluminum, oxygen and carbon present on the surface of the substrate were observed. The inset is a Si 2p high resolution photoelectron spectrum, which shows the absence of silicon oxide or silicate between the aluminum oxide film and the silicon substrate.

### EXAMPLE 2

The procedure of Example 1 was repeated except that dimethylaluminum sec-butoxide was used as an aluminum precursor. The photoelectron spectrum of the aluminum oxide film prepared in Example 2 also exhibited excellent properties without the problem of silicon oxide or silicate formation between the aluminum oxide film and the silicon substrate.

As can be seen from the above result, the process for preparing an aluminum oxide film by means of atomic layer deposition using a dialkyl aluminum alkoxide as an aluminum precursor, is much more advantageous than prior art processes.

While some of the preferred embodiments of the subject invention have been described and illustrated, various changes and modifications can be made therein without departing from the spirit of the present invention defined in the appended claims.

1. A process for preparing an aluminum oxide film on a substrate which comprises:
A) bringing the vapor of a dialkylaluminum alkoxide into contact with the substrate mounted in a deposition reactor so that an aluminum-containing adsorption layer is formed on the substrate;
B) removing the unreacted aluminum compound and by-products from the reactor;
C) introducing an oxygen source into the reactor so that the oxygen source reacts with the aluminum-containing adsorption layer to form an aluminum oxide layer; and
D) removing the unreacted oxygen source and by-products from the reactor.

2. The process of claim 1, wherein the cycle consisting of steps A) to D) is repeated until an aluminum oxide film of a desired thickness is obtained.

3. The process of claim 1, wherein the dialkylaluminum alkoxide is of the following formula:
R¹₂Al—O—R²
wherein R¹ and R² are each independently a C₁-C₄ alkyl.

4. The process of claim 1, wherein the dialkylaluminum alkoxide is selected from the group consisting of dimethylaluminum isopropoxide, dimethylaluminum tert-butoxide, diethylaluminum isopropoxide, dimethylaluminum sec-butoxide and a mixture thereof.

5. The process of claim 1, wherein the substrate is silicon.

6. The process of claim 1, wherein the oxygen source is oxygen, ozone or water.

7. The process of claim 1, wherein the substrate is maintained at a temperature in the range of 100 to 300° C.

8. The process of claim 1, wherein the dialkylaluminum alkoxide is dimethylaluminum isopropoxide and the oxygen source is water.

9. The process of claim 1, wherein the dialkylaluminum alkoxide is dimethylaluminum sec-butoxide and the oxygen source is water.

10. The process of claim 1, wherein each of the steps A) and C) is conducted for a period of 0.1 s or longer per cycle.

11. The process of claim 1, wherein each of the steps B) and D) is conducted by evacuating or purging with an inert gas.
